(19) United States
(12) Patent Application Publication
(10) Pub. No.: US 2026/0136467 A1
(43) Pub. Date: May 14, 2026

(54) APPARATUSES AND METHODS FOR FACILITATING A SUBSTRATE-TO-FLEX TRANSITION FOR HIGH-FREQUENCY AND HIGH-SPEED APPLICATIONS

(71) Applicant: CIENA CORPORATION, Hanover, MD (US)

(72) Inventors: Shuhui Deng, Nepean (CA); Hugues Tournier, Gatineau (CA)

(73) Assignee: CIENA CORPORATION, Hanover, MD (US)

(21) Appl. No.: 18/947,215

(22) Filed: Nov. 14, 2024

(51) Int. Cl. H05K 1/18; H05K 1/02; H05K 1/11; H05K 3/24

(52) U.S. Cl. CPC H05K 1/189; H05K 1/0216; H05K 1/118; H05K 3/244; H05K 2201/0154; H05K 2201/09227

(57) ABSTRACT

Aspects of the subject disclosure may include, for example, a structure or apparatus for use as part of one or more circuits. The structure may include a first region including a flexible circuit, a second region including a transition region, the second region coupled to the first region, and a third region including a substrate region, the third region coupled to the second region. A solder height or distance between the flexible circuit and the substrate region may be equal to approximately 50 micrometers. Other embodiments are disclosed.

### FIELD OF THE DISCLOSURE

The subject disclosure relates to apparatuses and methods for facilitating a substrate-to-flex transition for high-frequency and high-speed applications.

### BACKGROUND

With advancements in integrated circuit (IC) technologies, IC manufacturers and fabricators have been able to accommodate increased functionality, at increased speeds/frequencies, within a given package. Conventionally, ICs are fabricated utilizing a structure formed from a printed circuit board (PCB), a ball grid array (BGA), and packaging (e.g., “PCB+BGA balls+Package”). However, testing/analyses have shown that such a structure can only provide or support a bandwidth of approximately 65 GHz. What this means in practice is that the structure serves as a bottleneck or limiting constraint to continued advancements in support of high-speed/high-frequency, data-intensive/data-rich applications and communication services.

### BRIEF DESCRIPTION OF THE DRAWINGS

The patent or application file contains at least one drawing executed in color. Copies of this patent or patent application publication with color drawing(s) will be provided by the Office upon request and payment of the necessary fec.

Reference will now be made to the accompanying drawings, which are not necessarily drawn to scale, and wherein:

FIG. 1 is a block diagram illustrating an exemplary, non-limiting embodiment of a flex-to-transition-to-substrate structure in accordance with various aspects described herein.

FIGS. 2A-2F illustrate features of a flex region and a transition region of a structure in accordance with aspects of this disclosure.

FIG. 2G depicts a substrate formed to include multiple layers in accordance with aspects of this disclosure.

FIGS. 2H-2I illustrate a stackup of a first design for a flex-transition structure featuring a first material thickness in accordance with aspects of this disclosure.

FIGS. 2J-2K illustrate a stackup of a second design for a flex-transition structure featuring a second material thickness in accordance with aspects of this disclosure.

FIG. 2L illustrates a close-up view of a signal trace formed to include various portions, inclusive of a notch portion, in accordance with aspects of this disclosure.

FIGS. 3A-3B illustrate a use of a coverlay as part of a structure in accordance with aspects of this disclosure.

FIG. 4 illustrates a structure that facilitates soldering in a cone-like/conical shape in accordance with aspects of this disclosure.

FIGS. 5A-5I illustrate features of a L5 design in accordance with aspects of this disclosure.

FIGS. 6A-6C illustrate features of a L3 design in accordance with aspects of this disclosure.

FIGS. 7A-7C illustrate features of a L1 design in accordance with aspects of this disclosure.

FIGS. 7D-7F illustrate features of a variant of the L1 design of FIGS. 7A-7C in accordance with aspects of this disclosure.

### DETAILED DESCRIPTION

The subject disclosure describes, among other things, illustrative embodiments for enhancing signaling speeds and supported signaling/communication bandwidths in conjunction with circuit (e.g., integrated circuit) design and configuration. Other embodiments are described in the subject disclosure.

One or more aspects of the subject disclosure include, in whole or in part, an apparatus that includes: a first region including a flexible circuit; a second region including a transition region, the second region coupled to the first region; and a third region including a substrate region, the third region coupled to the second region, wherein a solder height between the flexible circuit and the substrate region is equal to 50 micrometers+/−10%.

One or more aspects of the subject disclosure include, in whole or in part, an apparatus that includes: a flexible circuit; and a substrate region coupled to the flexible circuit via a solder material that includes a metal alloy, wherein a dimension of the solder material between the flexible circuit and the substrate region is equal to 50 micrometers+/−10%, and wherein the solder material is substantially cone-shaped.

One or more aspects of the subject disclosure include, in whole or in part, an apparatus that includes: a flexible circuit; and a substrate region coupled to the flexible circuit via a solder material, wherein a dimension of the solder material between the flexible circuit and the substrate region is equal to 50 micrometers+/−5%.

One or more aspects of this disclosure include, in whole or in part, an apparatus that includes: a first region including a flexible circuit; a transition region coupled to the first region; and a second region including a substrate, the second region coupled to the transition region, wherein the transition region comprises a first solder pad on the flexible circuit, a second solder pad on the substrate, and a conical solder portion connecting the first solder pad and the second solder pad.

By way of introduction, aspects of this disclosure may introduce or leverage a structure or apparatus formed from a flexible circuit or “flex” (e.g., a flexible printed circuit), a transition, and a substrate (e.g., “Flex+Transition+Substrate”), or associated regions. The structure may serve as a substitute or a replacement for a conventional structure “PCB+BGA balls+Package” of the type referred to above. The “Flex+Transition+Substrate” structure of this disclosure may support applications featuring high-speed/high-frequency signaling (e.g., a data-rate of approximately 900 GB/s, using 8-level pulse amplitude modulation (PAM8), supportive of up to 150 GHz bandwidth). Of course, other date-rates, modulation levels/orders and/or bandwidth values may be supported as part of various embodiments of this disclosure.

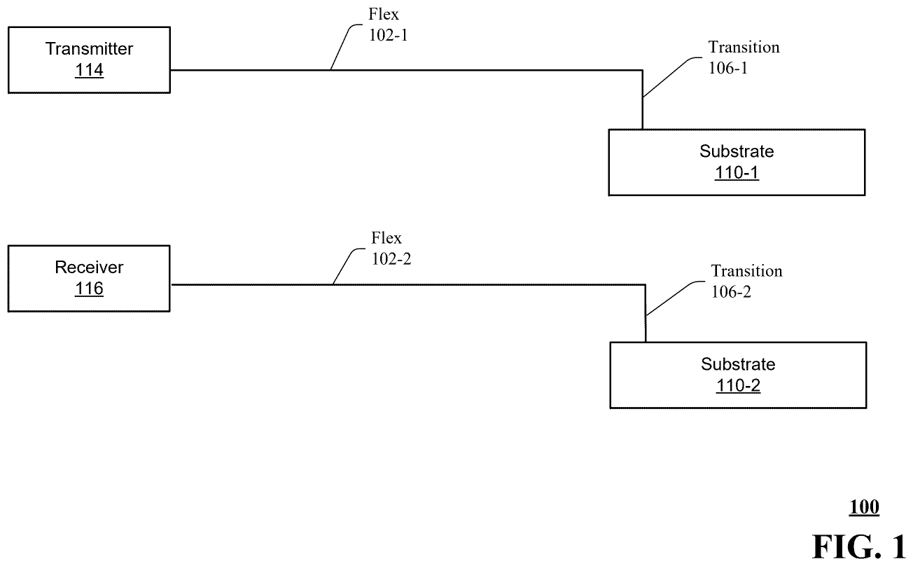

With the foregoing in mind, reference may now be made to FIG. 1, which is a block diagram illustrating an exemplary, non-limiting embodiment of structure 100 in accordance with aspects of this disclosure. The structure 100 may correspond to a “Flex+Transition+Substrate” structure of the type referred to above. In particular, the structure 100 is shown as being formed from a first flex 102-1, a first transition 106-1, and a first substrate 110-1, a second flex 102-2, a second transition 106-2, and a second substrate 110-2. The terms/qualifiers “first” and “second” are used in this context to denote a use in respect of a particular application or environment, where the “first” elements/members may be associated with a transmitter (see, e.g., transmitter 114) and the “second” elements/members may be associated with a receiver (see, e.g., receiver 116). The substrates 110-1, 110-2 may include or couple to one or more integrated circuits (e.g., ASICs) for processing signals received from the receiver 116 and/or provided to the transmitter 114. In some embodiments, the substrates 110-1, 110-2 may be a single substrate coupled to the first flex 102-1 and the second flex 102-2. In this regard, it is understood that a single instance (e.g., only the “first” elements/members) may be utilized in a given embodiment of this disclosure.

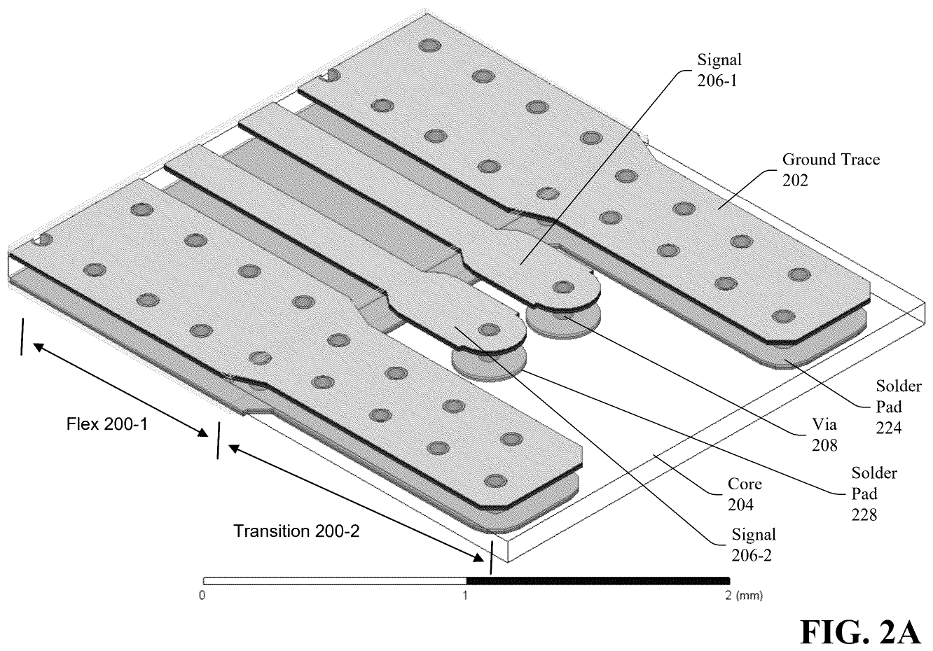

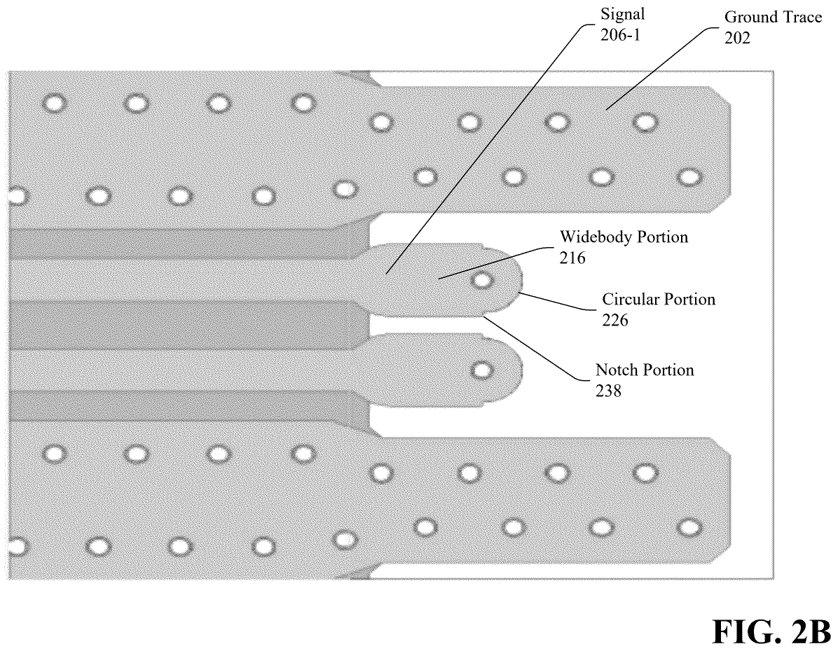

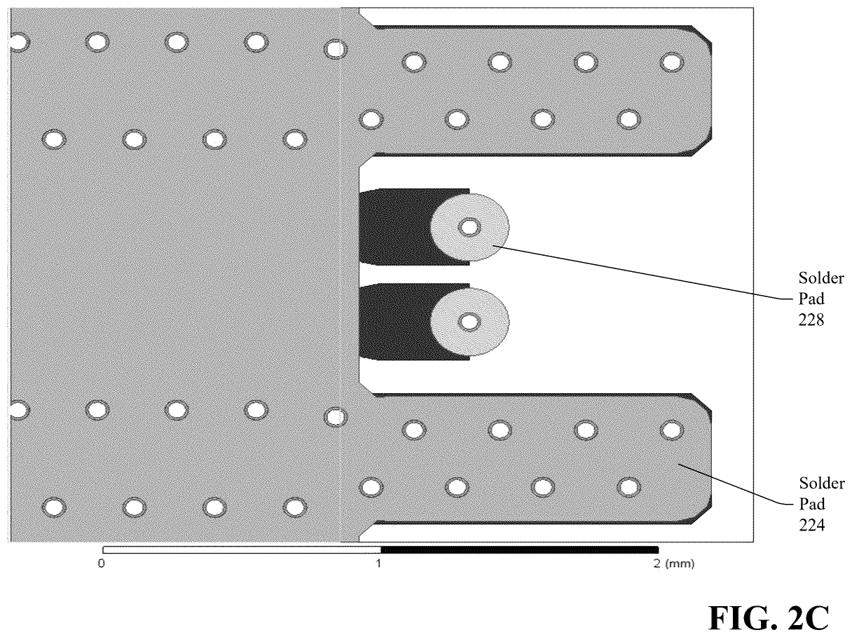

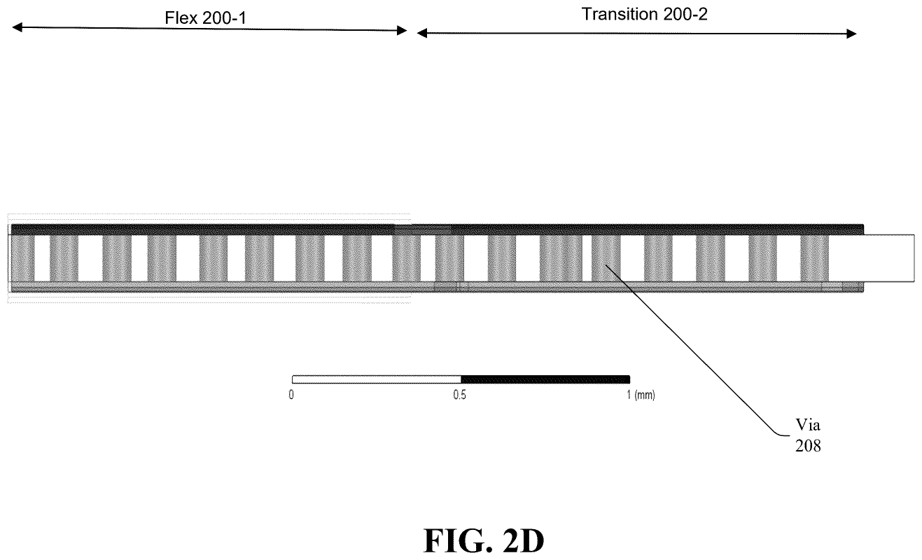

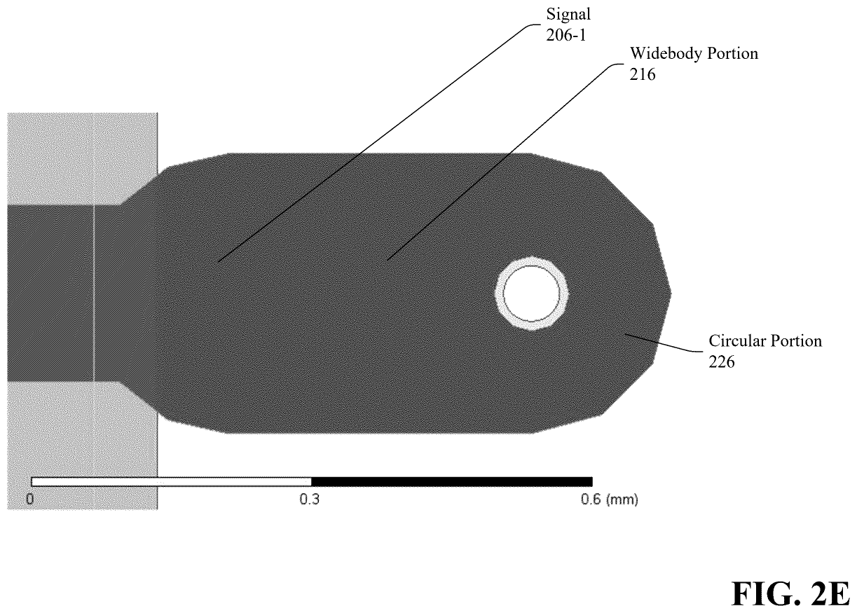

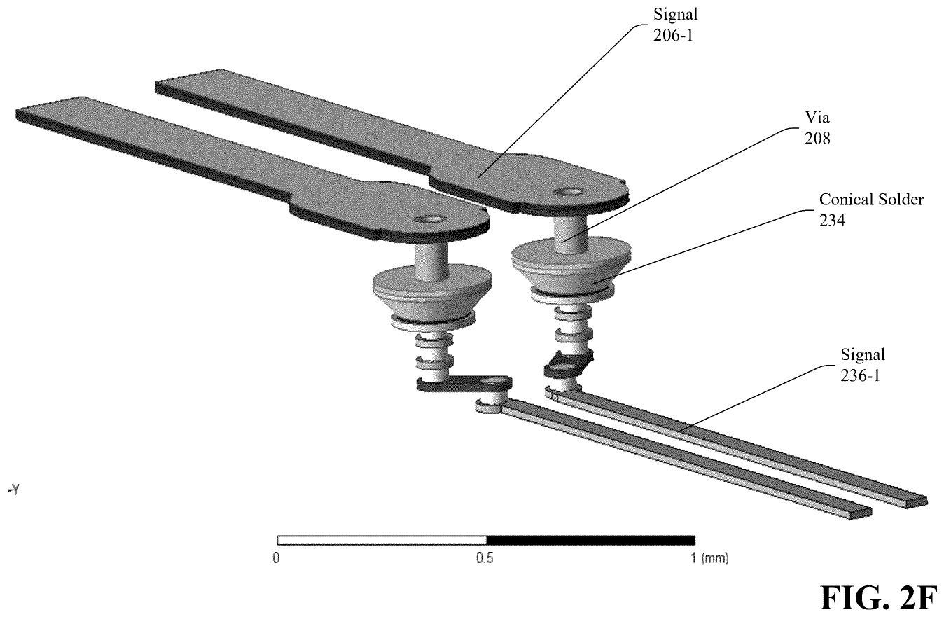

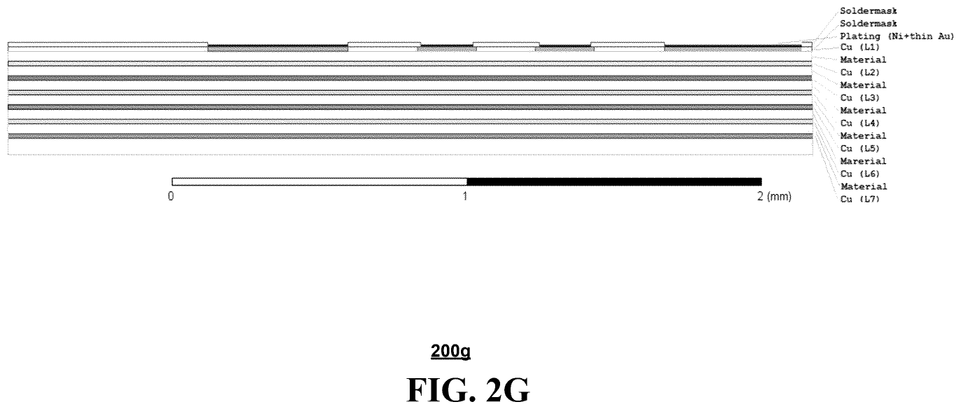

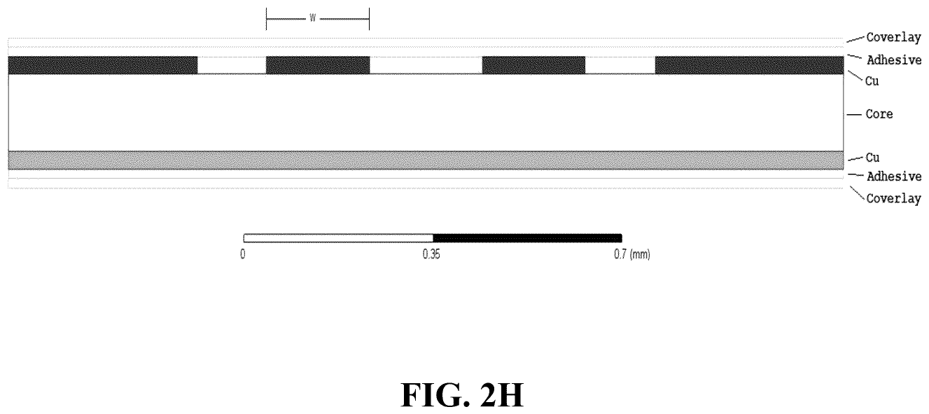

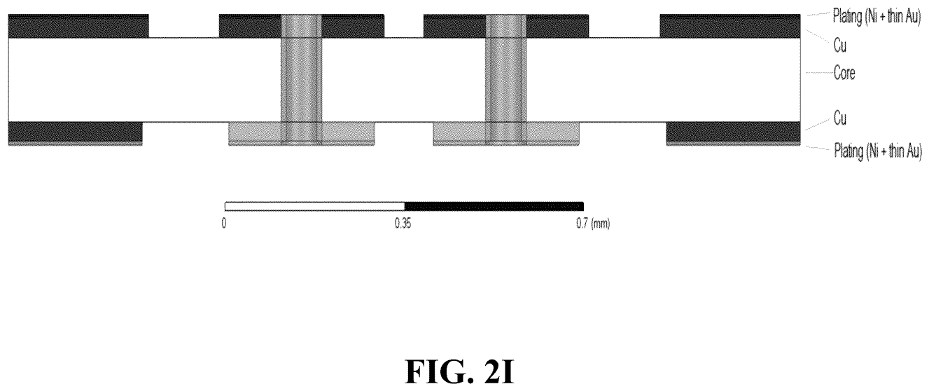

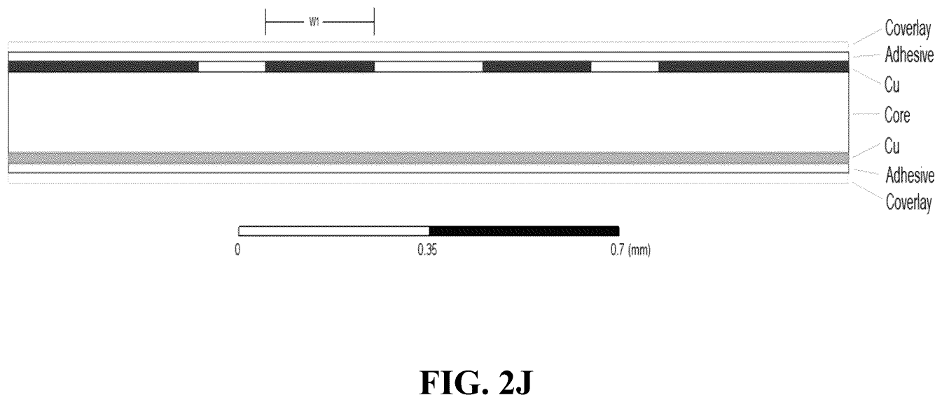

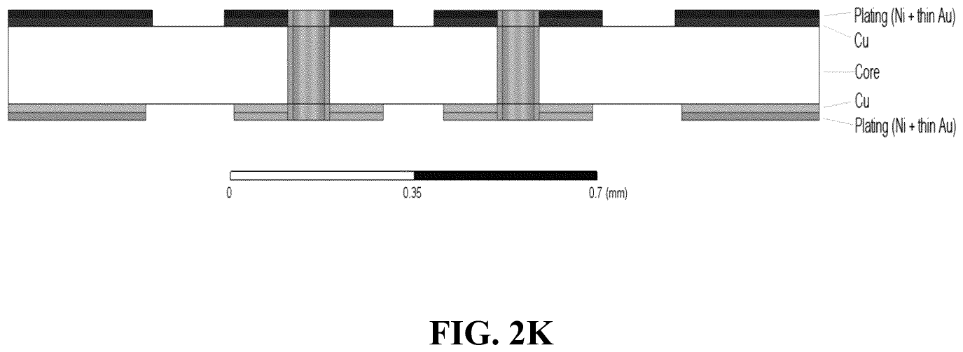

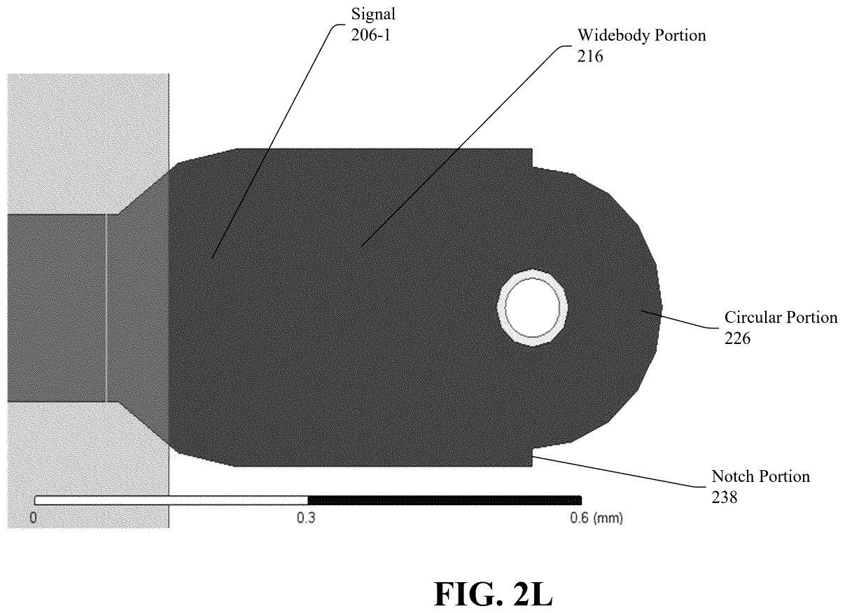

Referring now to FIG. 2A, an illustrative embodiment of a flex 200-1 and transition 200-2 in accordance with aspects of this disclosure is shown; see also FIG. 2B (bird's eye or top view corresponding to FIG. 2A), FIG. 2C (bottom view corresponding to FIG. 2A), FIG. 2D (side view corresponding to FIG. 2A); FIG. 2H (demonstrating, as part of a first design featuring a use of copper with a thickness approximately equal to 22 um (+/−5%) as a design example, a flex with no plating for connecting a partial thin [electroless nickel immersion gold (ENIG)] plating of the transition signal trace with a width W), FIG. 2I (demonstrating, as part of the first design, a flex with partial thin (ENIG) plating in the transition area), FIG. 2J (demonstrating, as part of a second design featuring a use of copper with a thickness approximately equal to 12 um (+/−5%) as a design example, a flex with no plating for connecting a partial (ENIG) plating of the transition signal trace with a width W1 (where width W1 is greater than the aforementioned width W)), and FIG. 2K (demonstrating, as part of the second design, a flex with partial (ENIG) plating in the transition area). The different thicknesses described above in terms of the first design of FIGS. 2H and 2I and the second design of FIGS. 2J and 2K, may provide different performance characteristics, such as different impedance matching characteristics/capabilities, different loss(es), etc.

The flex and transition may include a number of features, such as a ground trace/pad 202, a core material 204, one or more signal traces (illustratively shown as a pair of signal traces 206-1 and 206-2, which may support differential signaling in some embodiments), and one or more solder features or elements, such as a solder pad 224 that is substantially associated with the ground trace 202 and a solder pad 228 that is substantially associated with a respective one of the signal traces. A via 208 is represented, where the via may be used to traverse different ones of the layers of a substrate (where such layers are described in further detail below in relation to, e.g., FIG. 2G). As seen in, e.g., FIGS. 2A-2C, the ground trace(s) 202/solder pad(s) 224 may assume a substantially U-shaped or C-shaped form factor (e.g., with an opening), and the signal traces 206-1, 206-2 and corresponding solder pad(s) 228 may be substantially recessed within the opening/cavity that is formed by way of the U/C shape.

In terms of enhancing performance (e.g., enhancing data-rate, enhancing bandwidth), the signal traces may be formed from one or more distinct portions or regions. In particular, and as illustratively shown in FIGS. 2B and 2L with respect to the signal trace 206-1, a signal trace of this disclosure may include a widebody/bulk portion 216, a (substantially) circular or semicircular portion 226, and a notch portion 238 that bridges/couples the widebody portion 216 and the circular portion 226. In another instance/embodiment shown in FIG. 2E, the signal trace may take on a reduced form that may omit the notch portion 238 (e.g., the widebody portion 216 may be blended or coupled more directly with respect to the circular portion 226 as shown in FIG. 2E). The inclusion of the notch portion 238 (as shown in, e.g., FIGS. 2B and 2L) may provide enhanced performance relative to the instance/embodiment shown in FIG. 2E; it may be the case that the instance/embodiment of FIG. 2E may be easier to manufacture/fabricate relative to the instance/embodiment featuring the inclusion of the notch portion 238. Briefly referring to FIG. 2F, the signal trace 206-1 is shown as transitioning to a signal trace 236-1 by way of a via 208, where the signal trace 206-1 and the signal trace 236-1 may appear on different layers. As shown in FIG. 2F, a conical solder portion 234 may be used/included and may connect, e.g., solder pads to one another.

By virtue of the arrangement shown in, e.g., FIGS. 2A-2F, a signal may be referred to as a “big diameter bottom solder pad pair+small diameter via pair+junction of big diameter top pad & wide trace pair for tuning”. The arrangement as shown may serve to balance impedance and facilitate tuning of electromagnetic (EM) fields, while providing excellent wide-band performance. Further, the arrangement may provide a large rectangular-like ground opening that may match substrate antipads/voids for facilitating a smooth transition.

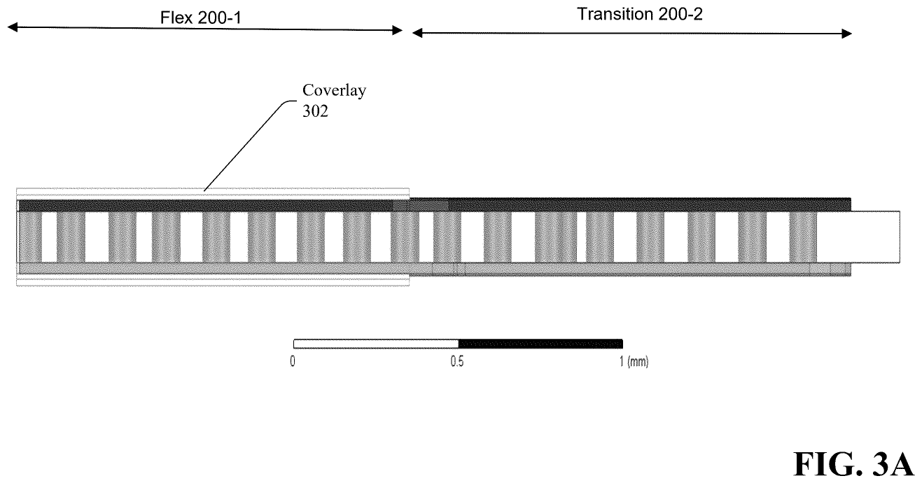

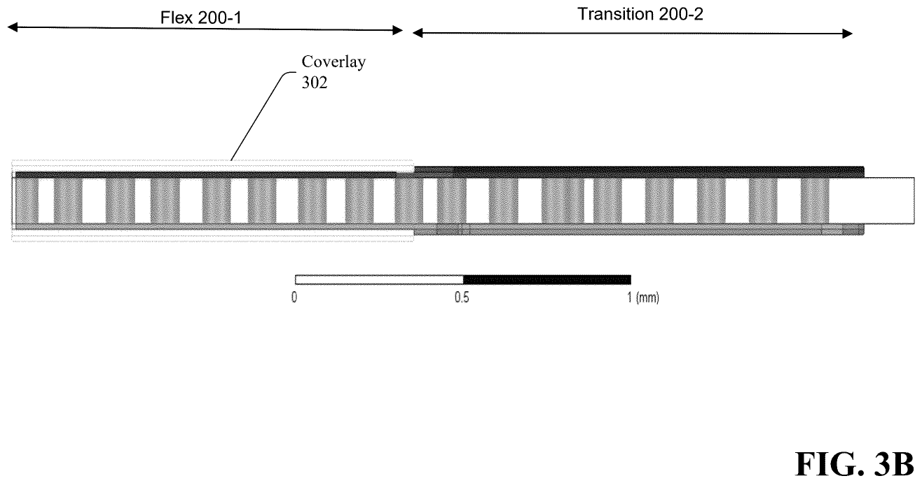

With reference to FIGS. 3A-3B (which depicts respective side views of two different design topologies/versions, where such different design topologies/versions may be used in conjunction with the first design and the second design, respectively, as described above in respect of FIGS. 2H-2I and FIGS. 2J-2K), in some embodiments a structure that is formed may include a coverlay 302 that may be made of one or more materials (e.g., pyralux, polyimide). The coverlay 302 may help to prevent corrosion and may be used to achieve lower insertion loss for budget margining with no plating on copper. The coverlay 302 may be included as part of the structure corresponding to the flex portion/region 200-1; e.g., the transition region 200-2 might not include such a coverlay. The transition region 200-2 may be formed to include electroless nickel immersion gold (ENIG) or electroless nickel electroless palladium immersion gold (ENEPIG) coating/plating as would be appreciated by one of skill in the art. Surface finishes may be applied to exposed surfaces in the transition region, like pads and vias.

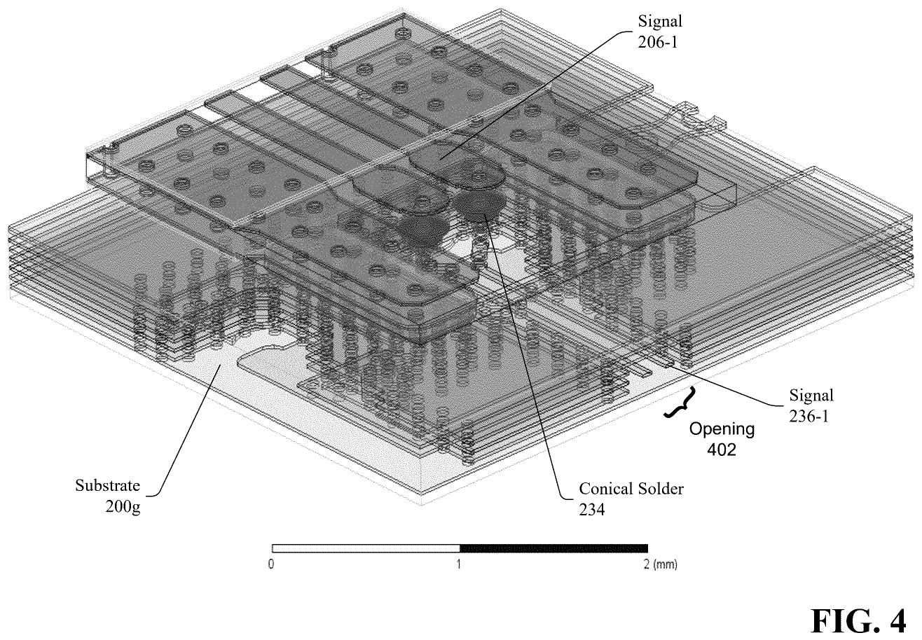

Referring now to FIG. 4, a transition (e.g., the transition 106-1 of FIG. 1, transition 200-2 of FIG. 2A) between a flex (e.g., the flex 102-1 of FIG. 1, flex 200-1 of FIG. 2A) and a substrate (e.g., the substrate 110-1 of FIG. 1, substrate 200g of FIG. 2G) is shown in further detail. In particular, as represented in FIG. 2F and FIG. 4, flex-to-substrate soldering, by way of the transition, may enable/provide for a conical solder 234 to be used. A smooth connection from the “big diameter bottom solder pad” of the flex to the “small top solder pad” of the substrate (see, e.g., FIGS. 2F and 4A) may be obtained/realized. In some embodiments, the specified solder height/distance may be equal to 50 micrometers (+/−10%, +/−5%, +/−2%, etc.), which may be much smaller/shorter than a BGA solder ball. This reduction in height/distance may facilitate at least some of the performance gains referenced above. The solder height/distance may be based on a dimension of a solder material that may be used. The solder material may include a metal or metal alloy that may be formed from or include tin, lead, copper, silver, and/or antimony; other materials may be used in some embodiments.

As shown in FIG. 4, the signal traces (e.g., signal trace 236-1) may traverse an opening or channel 402 formed in the substrate. Parameters (e.g., lengths, widths, proximity to other signals or grounds/ground planes, etc.) of the signal traces (e.g., signal trace 236-1) in the portion corresponding to the transition, or proximal to the label of the opening 402 of FIG. 4, may be selected or controlled to provide a number of features, such as impedance matching.

A substrate of this disclosure may incorporate a multi-layered design approach/topology. Sec, e.g., FIG. 2G (demonstrating a stack-up or layered assembly for a substrate 200g (illustratively with layers L1, L2, L3, L4, L5, L6, and L7, that may be used to alternate between signal and ground), with/using various types of materials—e.g., soldermask, plating (e.g., nickel, gold (Au)), copper (Cu), etc.). Features associated with various ones of the layers are described below. As set forth above, the layers may be referred to using different labels, e.g., L1, L2, L3, L4, L5, L6, L7, and so on, to distinguish amongst them (see, e.g., FIG. 2G for a representation of the layers).

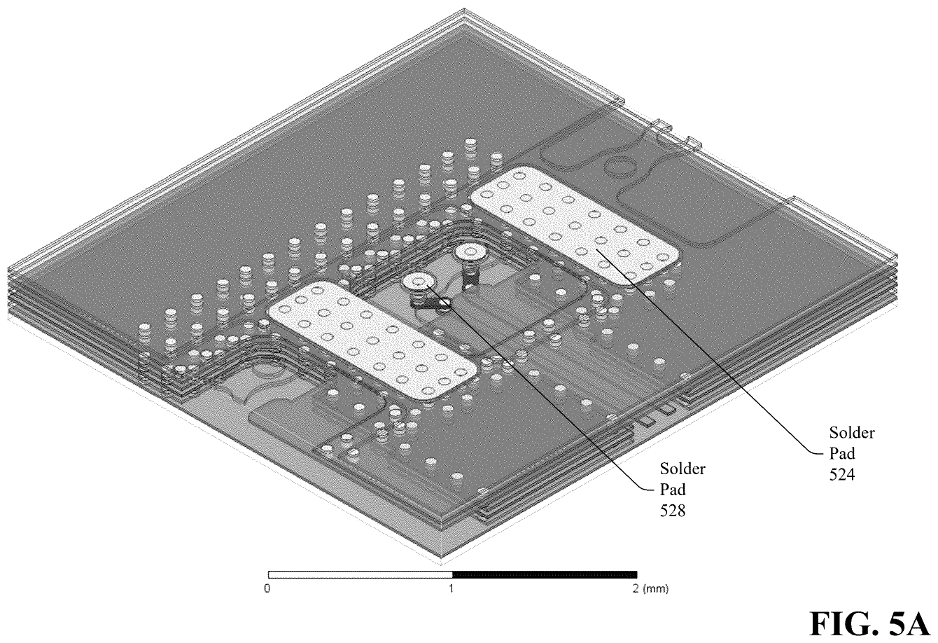

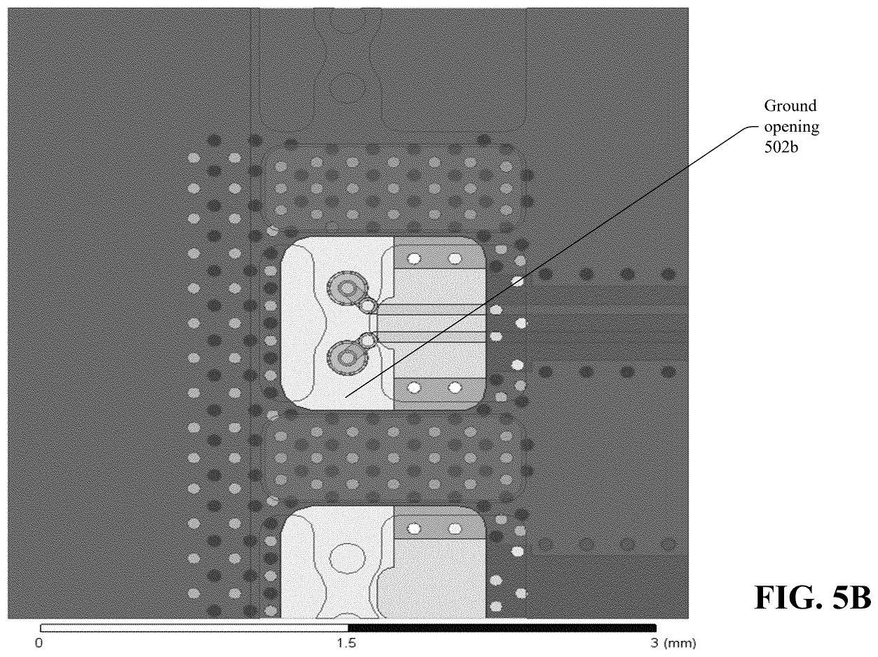

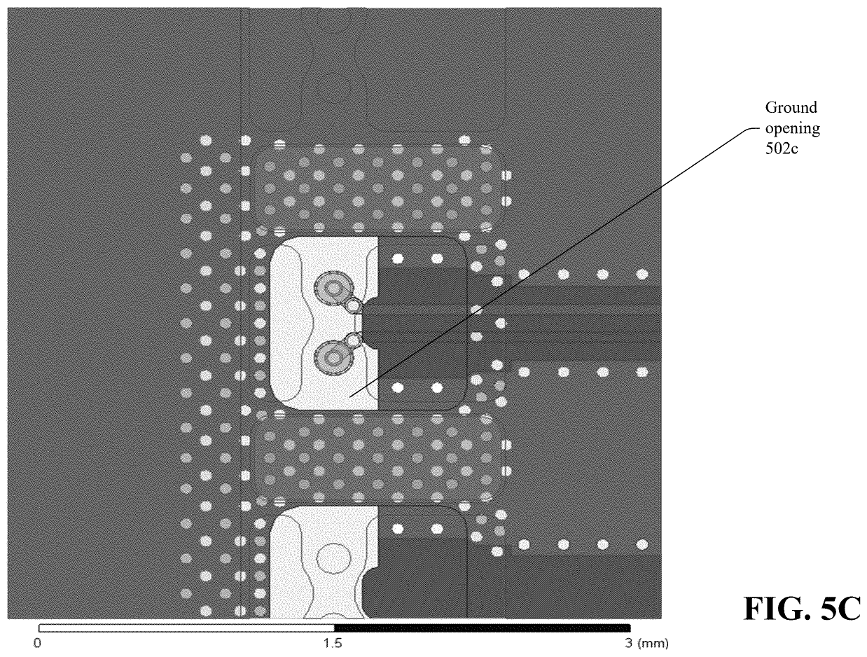

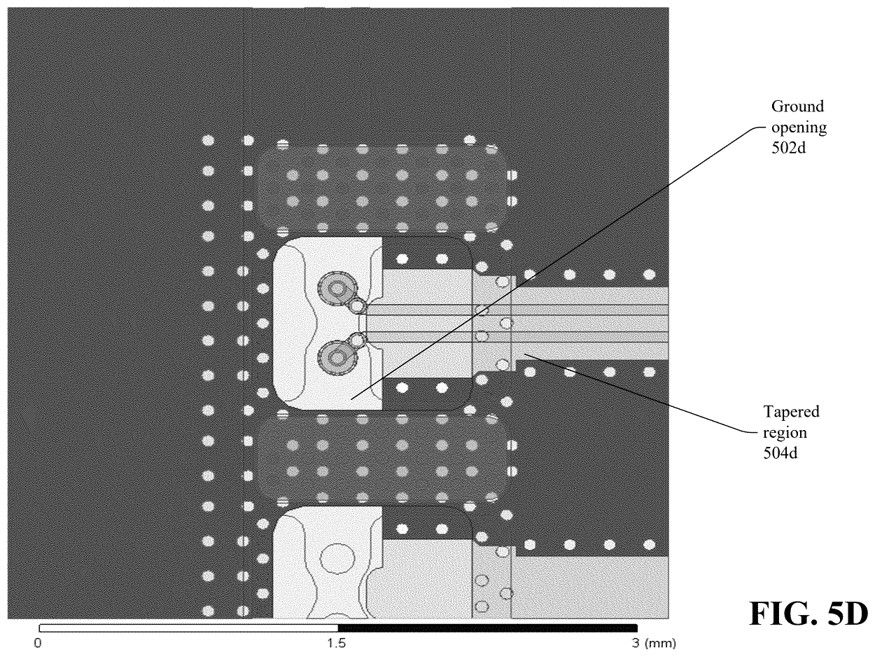

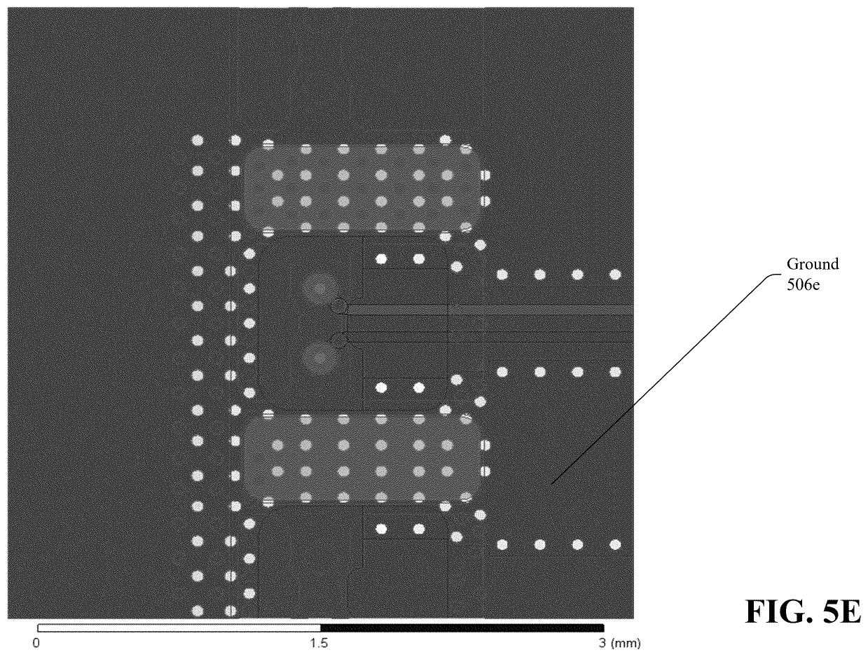

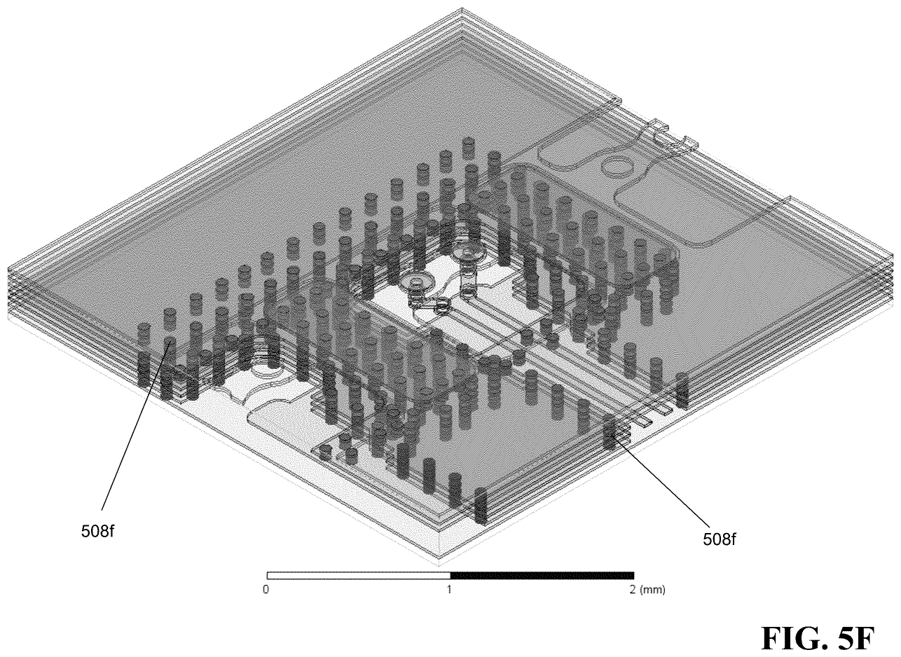

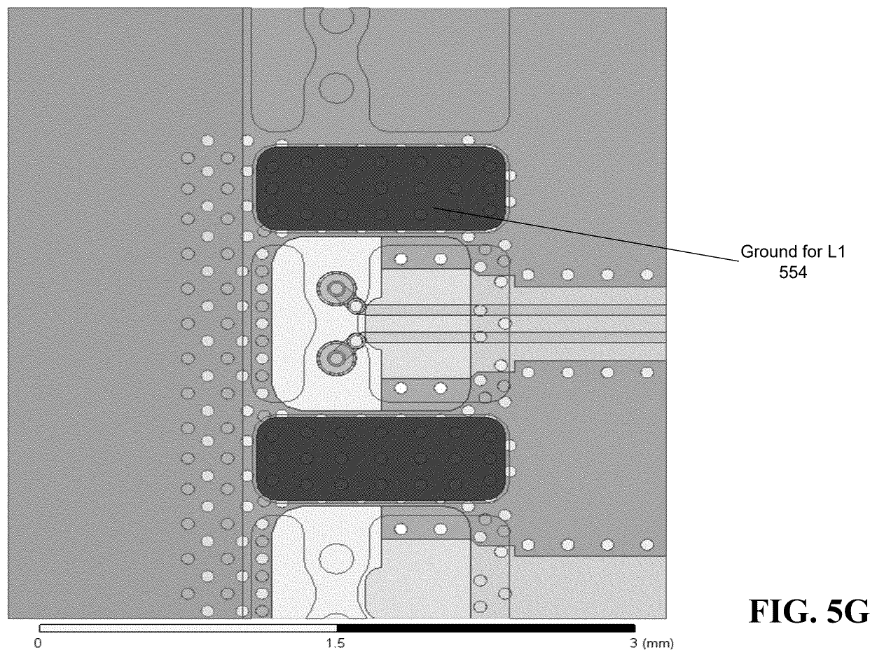

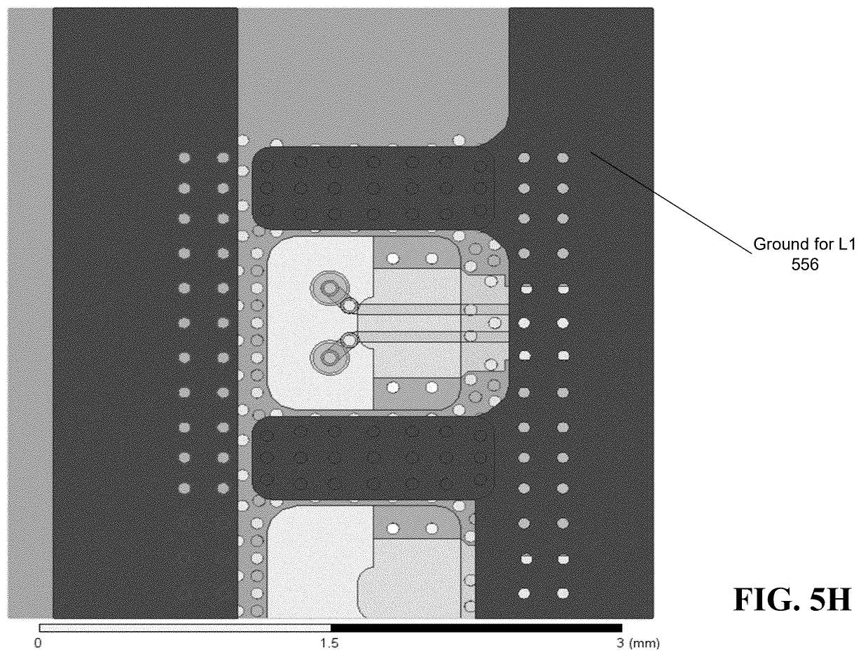

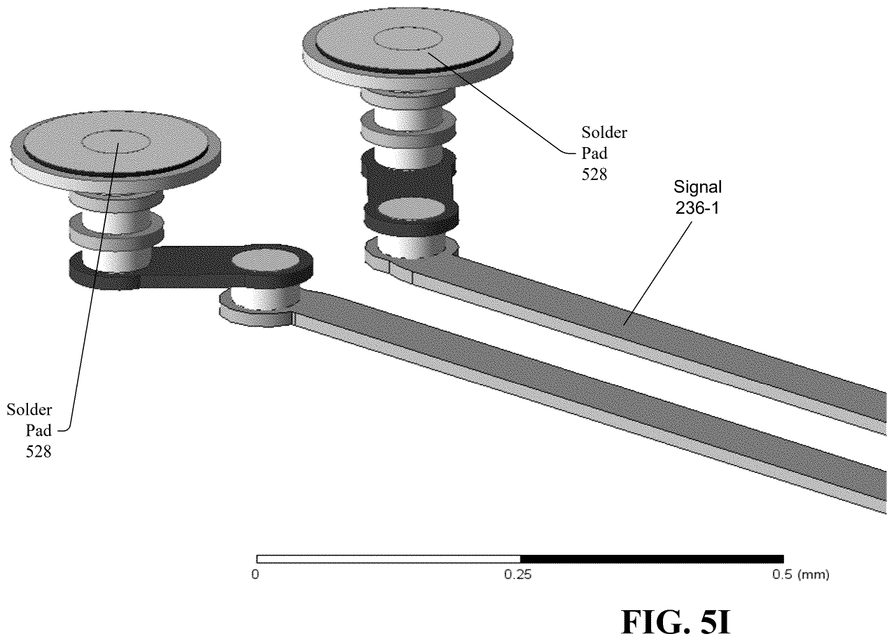

As shown in FIG. 5A, a solder pad 524 and a solder pad 528 may be included on a substrate, as part of, e.g., an L5 design. The solder pad 524 and the solder pad 528 may be used to mate/couple/attach to the solder pad 224 and solder pad 228, respectively, as shown in, e.g., FIGS. 2A and 2C.

Referring to FIG. 5B, a ground opening 502b is shown for, e.g., layer L2 as part of the L5 design. The ground opening 502b may be substantially square shaped, with one or more rounded edges or corners, as shown in FIG. 5B.

Referring to FIG. 5C, a ground opening and extension 502c is shown for, e.g., layer L3 as part of the L5 design. The ground opening 502c may be substantially shaped like half of a square, with one or more rounded edges or corners, as shown in FIG. 5C.

Referring to FIG. 5D, a ground opening 502d is shown for, e.g., layers L4, L5, and L6, as part of the L5 design. The ground opening 502d may be shaped similarly to the ground opening 502c of FIG. 5C. Also, the ground opening 502d may include, or be associated with, a stepped tapered region 504d as shown in FIG. 5D, where the stepped taper may assist in reducing insertion loss drop.

Referring to FIG. 5E, a ground 506e is shown for layer L7 as part of the L5 design. The ground 506e may be formed from one or more materials, e.g., copper. Reference may also be made to FIG. 5F, which depicts a distribution of ground vias 508f in accordance with aspects of this disclosure.

Referring to FIG. 5G, a ground 554 is shown for the layer L1 as part of the L5 design. The ground 554 may be formed from one or more materials, e.g., copper, gold, etc. The ground 554 may substantially correspond to the (footprint or profile of the) solder pad 524 of FIG. 5A. FIG. 5H illustrates a variation on FIG. 5G, wherein a ground 556 for the layer L1 is shown as part of the L5 design. The ground 556 may substantially include/encompass the solder pad 524 (see, e.g., FIG. 5A), but may extend even further beyond the profile of the solder pad 524. The use of the ground 554 in conjunction with FIG. 5G may provide for an adequate thermal profile/thermal management that may facilitate soldering (e.g., may be used to reduce a dissipation of heat across the surfaces). The use of the ground 556 in conjunction with FIG. 5H may also provide for reasonably good quality thermal characteristics to facilitate soldering, but may also provide a benefit of easily enabling alignment between, e.g., the substrate and the transition region.

Referring to FIG. 5I, another, closer view of, e.g., the solder pad 528 of FIG. 5A is shown. Furthermore, the signal trace 236-1 as it exists as part of the L5 design is also shown in FIG. 5I. As shown in FIG. 5I, the signal trace 236-1 for the L5 design may be substantially straight/linear, e.g., there might not be any bends (as contrasted with the various other shapes described below).

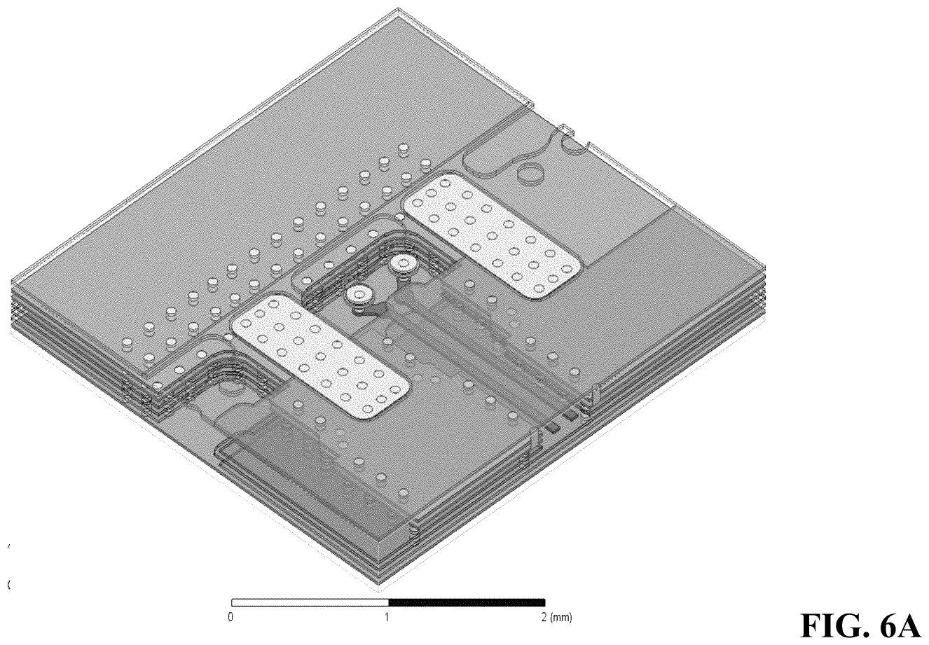

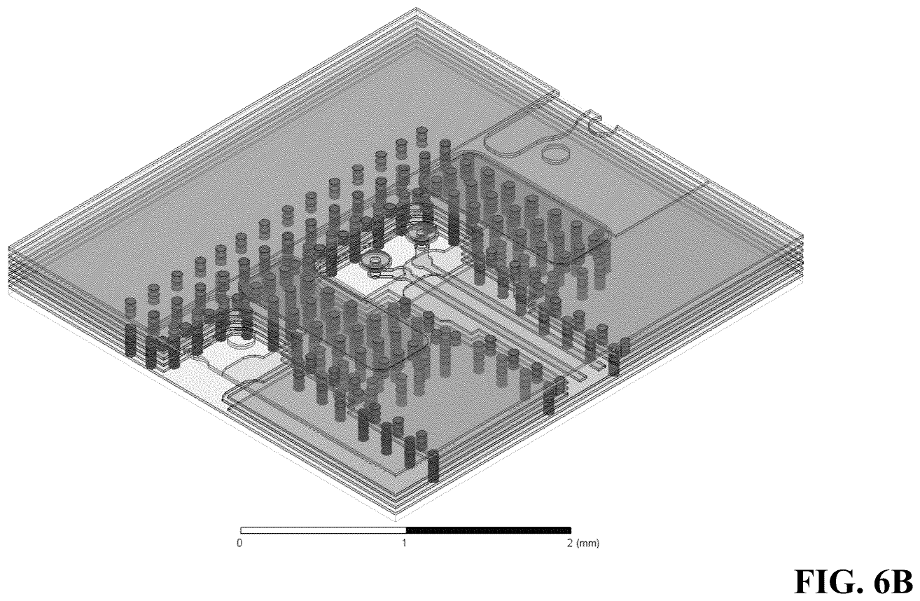

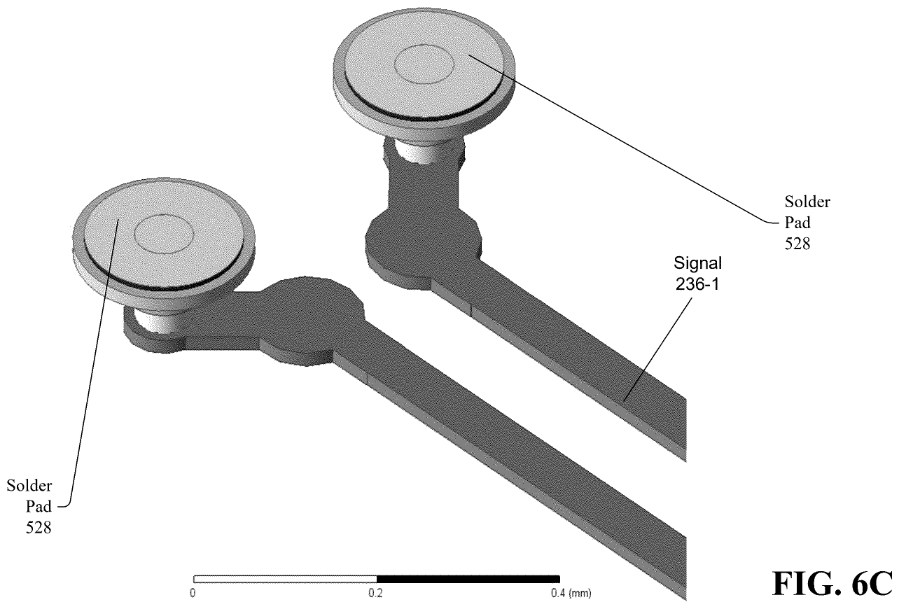

Referring now to FIG. 6A, a substrate L3 design is shown in a perspective view. Reference may also be made to the perspective view of the L3 design shown in FIG. 6B, inclusive of the ground via distribution (compare with FIG. 5F: showing ground via distribution for L5 design). The signal trace 236-1 for the L3 design is shown in FIG. 6C relative to, e.g., the solder pad(s) 528. The disk-like or circular-like turn joint (in FIG. 6C) is designed to tune the electromagnetic (EM) field for the signal trace from narrow to wide in the transition region. Data rates or signal/communication bandwidths associated with the arrangement shown in FIG. 6C as part of the L3 design may be greater/larger than the counterpart arrangement shown in FIG. 5I. This may be due to the smaller/shorter via lengths between, e.g., the solder pad 528 and the signal trace in the L3 design (FIG. 6C) compared to the via lengths between, e.g., the solder pad 528 and the signal trace in the L5 design (FIG. 5I).

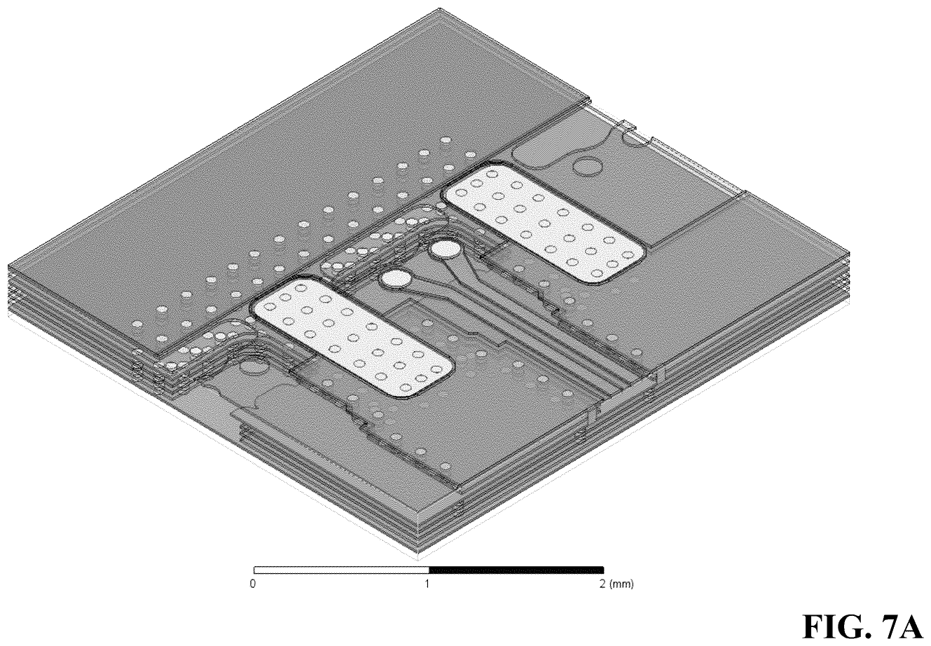

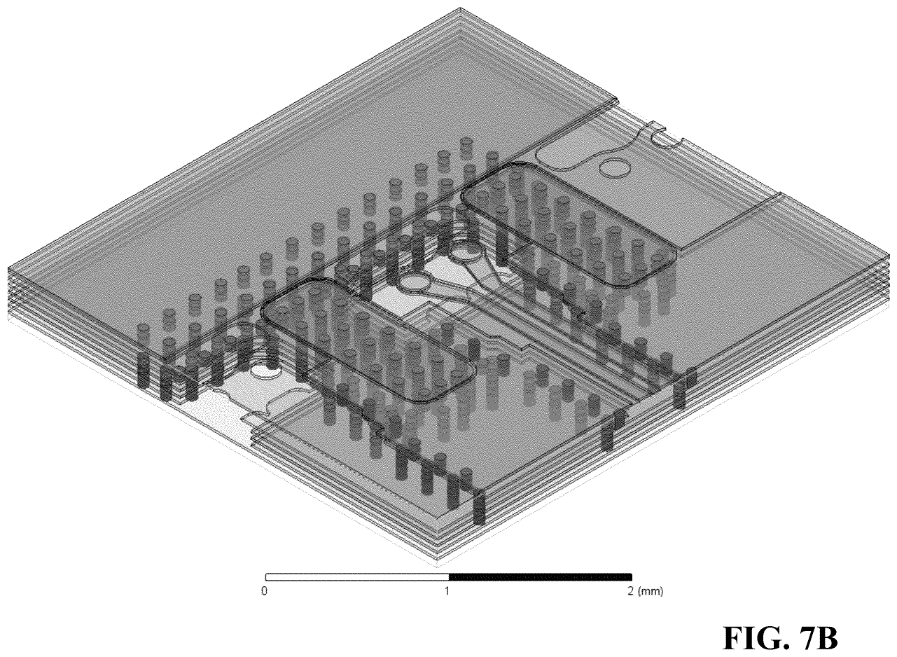

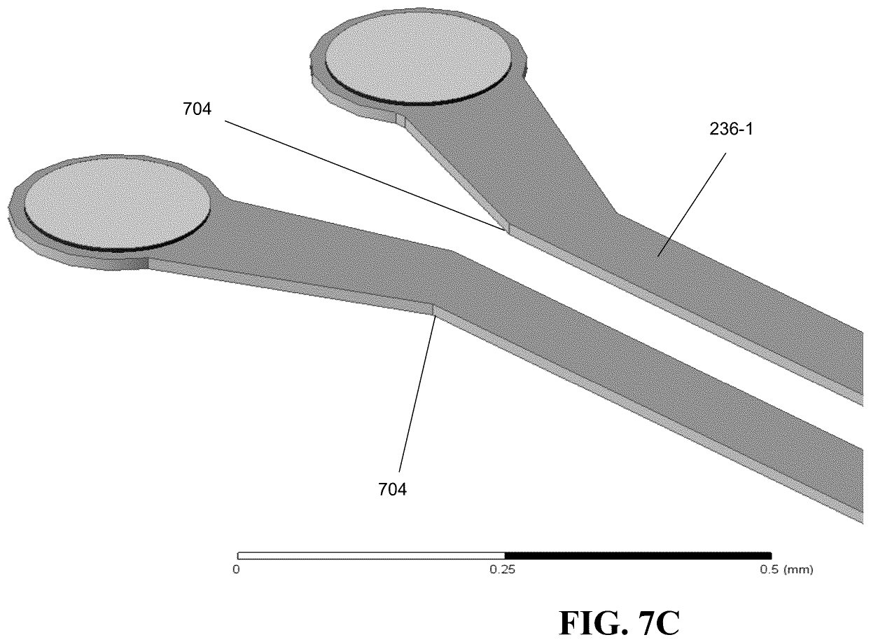

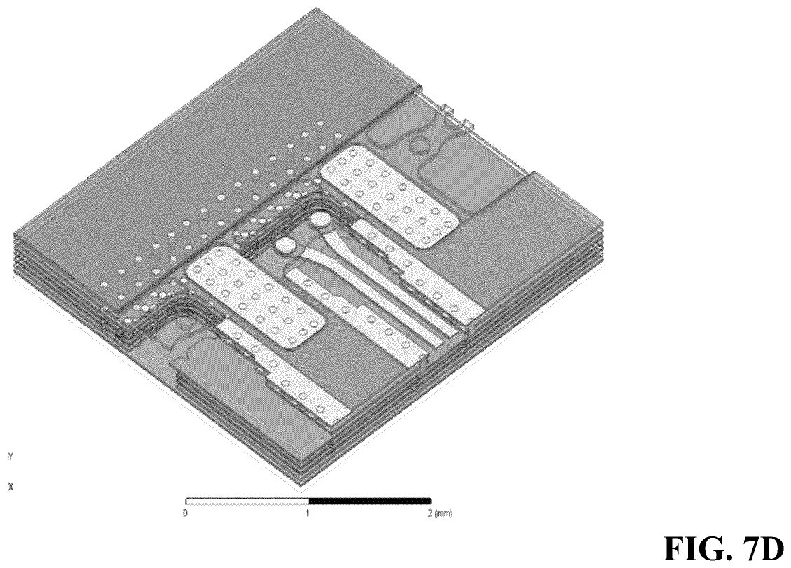

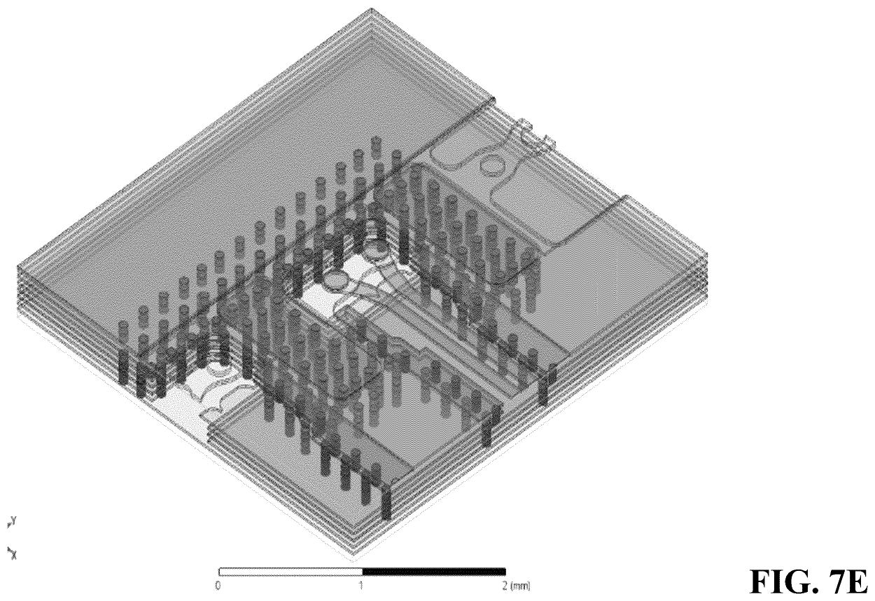

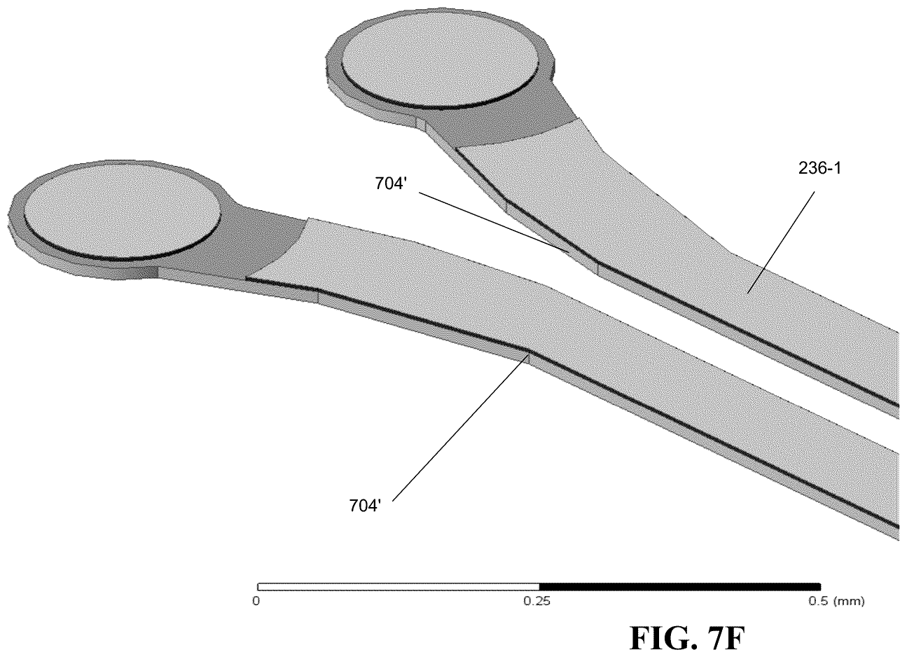

Referring now to FIG. 7A, a substrate L1 design is shown in a perspective view. Reference may also be made to the perspective view of the L1 design shown in FIG. 7B, inclusive of the ground via distribution (compare with FIG. 5F: showing ground via distribution for L5 design and FIG. 6B: showing ground via distribution for L3 design). FIG. 7C illustrates the signal trace 236-1 as it exists as part of the L1 design of, e.g., FIG. 7A. In particular, the signal traces shown in FIG. 7C may include relatively sharp/pronounced bends or angles 704, such that the signal traces may be described as including or forming a corner.

A variant of the substrate L1 design of FIGS. 7A-7C is shown in FIGS. 7D-7F, respectively. In particular, FIG. 7D demonstrates the variant of the L1 design in a perspective view and FIG. 7E shows the perspective view of the variant of the L1 design, inclusive of the ground via distribution. FIG. 7F illustrates the signal trace 236-1 as it exists as part of the variant of the L1 design of, e.g., FIG. 7D. In particular, the signal traces shown in FIG. 7F may include subtle bends or curves 704′, such that the signal traces may be described as being substantially curved or including a curve.

The different shapes of the signal traces (e.g., linear, non-linear, curved, bends/angles, etc.) shown and described above in respect of, e.g., FIG. 5I, FIG. 7C, and FIG. 7F may provide for a number of different performance features or characteristics. In L1 design of FIGS. 7A-7C, signal traces are covered by partial solder mask with no plating except solder pads to achieve much lower insertion loss for long substrate routes. In the substrate L1 design in FIGS. 7D-7F, signal traces are covered by plating except the solder mask around solder pads to achieve more accurate impedance control for long substrate routes on L1 layer.

Embodiments of this disclosure may include/incorporate one or more solder pads and/or solder masks. The design for substrate solder pad size and shape, and solder mask clearance size and shape, may be selected to achieve particular goals or objectives. For example, the solder mask clearance size may be smaller than the solder pad size to reduce (e.g., prevent) solder overflow and may be used to tune EM field(s) in the transition. Shapes for features of solder pads or solder masks may be substantially circular, rectangular, oval, square, etc., in some embodiments.

As described above, aspects of this disclosure (inclusive of aspects of one or more structures described herein) may be utilized in provisioning various communication services. Aspects of this disclosure may be used to enhance the speed or data-rate associated with various applications. Stated differently, aspects of this disclosure may facilitate a use, and existence of, high-speed/high-frequency applications, where such applications would not be technologically possible/feasible in the absence of the technology of this disclosure.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Aspects of this disclosure may be utilized in respect of one or more computing devices. Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. An apparatus comprising:
a first region including a flexible circuit;
a transition region coupled to the first region; and
a second region including a substrate, the second region coupled to the transition region,
wherein the transition region comprises a first solder pad on the flexible circuit, a second solder pad on the substrate, and a conical solder portion connecting the first solder pad and the second solder pad.

2. The apparatus of claim 1, wherein a solder height associated with the conical solder portion is equal to 50 micrometers+/−10%.

3. The apparatus of claim 2, wherein the solder height is equal to 50 micrometers+/−5%.

4. The apparatus of claim 3, wherein the solder height is equal to 50 micrometers+/−2%.

5. The apparatus of claim 1, wherein a first end of the conical solder portion contacting the first solder pad is larger than a second end of the conical solder portion contacting the second solder pad.

6. The apparatus of claim 1, wherein the first solder pad is larger than the second solder pad.

7. The apparatus of claim 1, wherein the transition region includes a first signal trace and a second signal trace on the flexible circuit.

8. The apparatus of claim 7, wherein the first signal trace includes a widebody portion and a semicircular portion.

9. The apparatus of claim 8, wherein the first signal trace includes a notch portion disposed between the widebody portion and the semicircular portion.

10. The apparatus of claim 1, wherein a coverlay is applied to the first region.

11. The apparatus of claim 10, wherein the coverlay is formed from a material, the material including pyralux, polyimide, or a combination thereof.

12. The apparatus of claim 1, wherein the transition region includes an electroless nickel immersion gold (ENIG) coating or an electroless nickel electroless palladium immersion gold (ENEPIG) coating.

13. The apparatus of claim 1, wherein a layer of the substrate includes a stepped taper ground opening for a plurality of other layers of the substrate to reduce insertion loss drop.

14. The apparatus of claim 1, wherein a pair of differential signal traces is included on a layer of the substrate, and wherein a turn joint in each of the differential signal traces is disk-like or circular-like.

15. The apparatus of claim 1, wherein a pair of differential signal traces is included on a first layer of the substrate, and wherein a bend in each of the differential signal traces is substantially curved.

16. The apparatus of claim 1, wherein a pair of differential signal traces is included on a first layer of the substrate, and wherein a bend in each of the differential signal traces forms a corner.

17. An apparatus comprising:
a flexible circuit; and
a substrate region coupled to the flexible circuit via a solder material that includes a metal alloy,
wherein a dimension of the solder material between the flexible circuit and the substrate region is equal to 50 micrometers+/−10%, and wherein the solder material is substantially cone-shaped.

18. The apparatus of claim 16, further comprising:
a transition region disposed between the flexible circuit and the substrate region.

19. The apparatus of claim 17, wherein the transition region includes an electroless nickel immersion gold (ENIG) coating or an electroless nickel electroless palladium immersion gold (ENEPIG) coating.

20. An apparatus comprising:
a flexible circuit; and
a substrate region coupled to the flexible circuit via a solder material,
wherein a dimension of the solder material between the flexible circuit and the substrate region is equal to 50 micrometers+/−5%.
